(19) United States
(12) Patent Application Publication
(10) Pub. No.: US 2008/0296142 A1
(43) Pub. Date: Dec. 4, 2008

(54) SWINGING MAGNETS TO IMPROVE TARGET UTILIZATION

(76) Inventors: HIEN-MINH HUU LE, San Jose, CA (US); BRADLEY O. STIMSON, Monte Sereno, CA (US); JOHN M. WHITE, Hayward, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/754,983

(22) Filed: May 29, 2007

(51) Int. Cl. C23C 14/00; C25B 5/00

(52) U.S. Cl. 204/155; 204/298.2

(57) ABSTRACT

A method and apparatus for uniformly eroding a sputtering target is disclosed. As a racetrack shaped magnetic field formed by a magnetron moves across the sputtering surface of the sputtering target, one or more magnets within the magnetron may swing or pivot relative to other magnets within the magnetron to reduce magnetic field pinching at the turns in the racetrack shaped magnetic field. The swinging or pivoting magnets alter the location on the magnetic field at a turn in the racetrack shape where the coordinate of the magnetic field perpendicular to the sputtering surface equals zero. By altering the location, sputtering target erosion uniformity may be increased.

### BACKGROUND OF THE INVENTION

1. Field of the Invention

Embodiments of the present invention generally relate to a magnetron for a physical vapor deposition (PVD) apparatus and a PVD method using the magnetron.

2. Description of the Related Art

PVD using a magnetron is one method of depositing material onto a substrate. During a PVD process a target may be electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, nitrogen, to reactively deposit a compound on the substrate. Reactive sputtering is often used to form thin barrier and nucleation layers of titanium nitride or tantalum nitride on the substrate.

Direct current (DC) sputtering and alternating current (AC) sputtering are forms of sputtering in which the target is biased to attract ions towards the target. The target may be biased to a negative bias in the range of about −100 to −600 V to attract positive ions of the working gas (e.g., argon) toward the target to sputter the atoms. Usually, the sides of the sputter chamber are covered with a shield to protect the chamber walls from sputter deposition. The shield may be electrically grounded and thus provide an anode in opposition to the target cathode to capacitively couple the target power to the plasma generated in the sputter chamber.

The magnetron may be used in sputtering to confine a large number of the ions in a magnetic field. By confining a large number of the ions, the amount of material sputtered may be increased in the area encompassed by the magnetic field because a greater number of ions may collide with the sputtering target and sputter atoms from the target. By confining a large number of ions, a high density plasma may be created that may increase the sputtering rate and help control the erosion uniformity of the sputtering target.

There is a need in the art for an improved magnetron that can increase the sputtering rate while also increasing the target erosion uniformity.

### SUMMARY OF THE INVENTION

A method and apparatus for uniformly eroding a sputtering target is disclosed. As a racetrack shaped magnetic field formed by a magnetron moves across the sputtering surface of the sputtering target, one or more magnets within the magnetron may swing or pivot relative to other magnets within the magnetron to reduce magnetic field pinching at the turns in the racetrack shaped magnetic field. The swinging or pivoting magnets alter the location on the magnetic field at a turn in the racetrack shape where the coordinate of the magnetic field perpendicular to the sputtering surface equals zero. By altering the location, sputtering target erosion uniformity may be increased.

In one embodiment, a sputtering apparatus is disclosed that comprises a magnetron assembly, one or more movement devices coupled with the magnet assembly capable of providing movement to the magnetron assembly, and a restraining mechanism coupled with one or more magnets within the magnetron assembly capable of producing a swinging movement of the one or more magnets within the magnet assembly. The magnetron assembly may be arranged in a racetrack pattern and comprise a plurality of magnets.

In another embodiment, a sputtering apparatus is disclosed comprising a moveable magnetron assembly having a plurality of magnets therein and an arm moveable in only one direction within the plane coupled with one or more magnets within the magnetron assembly. The magnetron assembly is moveable as a whole within a plane.

In yet another embodiment, a magnetron assembly is disclosed comprising a magnet support, a plurality of magnets coupled with the magnet support, one or more movement devices coupled with the magnet support capable of moving the magnet support within a plane, and an arm moveable in only one direction within the plane and coupled with one or more magnets of the plurality of magnets.

In still another embodiment, a sputtering method is disclosed comprising moving a magnetron assembly behind a sputtering target assembly, the magnetron assembly comprising a plurality of magnets, and swinging one or more magnets within the magnet assembly as the magnet assembly moves.

In another embodiment, a sputtering method is disclosed comprising moving a magnetic field across a face of a sputtering target, the magnetic field comprising a point where the magnetic field consists of a component parallel to the target face and changing a location of the point within the magnetic field as the magnetic field moves.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a PVD apparatus 100 according to one embodiment of the invention.

FIG. 2 is a top view of a magnetron assembly 200 according to one embodiment of the present invention.

FIG. 3A is a partial schematic view of a magnetron assembly 300 with the corresponding magnetic field.

FIG. 3B is a partial cross sectional view of a sputtering target assembly 350 having non-uniform sputtering target erosion.

FIG. 4A is a partial schematic view of a magnetron assembly 400 according to one embodiment of the invention.

FIG. 4B is a partial schematic view of a magnetron assembly 450 according to another embodiment of the invention.

FIGS. 5A-5C are schematic cross-sectional views of a magnetron assembly 500 having a swinging magnet 504 at various locations according to one embodiment of the invention.

FIG. 6A is a schematic view of various locations showing the point where the Y-component of the magnetic field is substantially equal to zero as the magnets swing.

FIG. 6B is a schematic view of the average of the various locations where the Y-component of the magnetic field is substantially equal to zero as the magnets swing.

FIG. 6C is a schematic cross sectional view of a sputtering target assembly 650 with corresponding target erosion resulting from a swinging magnet.

FIG. 7 is a schematic top view of a magnetron assembly 700 according to another embodiment of the invention.

FIG. 8 is a schematic top view of a magnetron assembly 800 according to another embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

A method and apparatus for uniformly eroding a sputtering target is disclosed. As a racetrack shaped magnetic field formed by a magnetron moves across the sputtering surface of the sputtering target, one or more magnets within the magnetron may swing or pivot relative to other magnets within the magnetron to reduce magnetic field pinching at the turns in the racetrack shaped magnetic field. The swinging or pivoting magnets alter the location on the magnetic field at a turn in the racetrack shape where the coordinate of the magnetic field perpendicular to the sputtering surface equals zero. By altering the location, sputtering target erosion uniformity may be increased.

The invention is illustratively described and may be used in a PVD system for processing large area substrates, such as a PVD system, available from AKT®, a subsidiary of Applied Materials, Inc., Santa Clara, Calif. However, it should be understood that the sputtering target may have utility in other system configurations, including those systems configured to process large area round substrates. An exemplary system in which the present invention may be practiced is described in U.S. patent application Ser. No. 11/225,922, filed Sep. 13, 2005, which is hereby incorporated by reference in its entirety.

As the demand for larger flat panel displays increases, so must the substrate size. As substrate size increases, so must the size of the sputtering target. For flat panel displays and solar panels, sputtering targets having a length of greater than 1 meter are not uncommon. Producing a unitary sputtering target of substantial size from an ingot can prove difficult and expensive. For example, it is difficult to obtain large molybdenum plates (i.e., 1.8 m×2.2 m×10 mm, 2.5 m×2.8 m×10 mm, etc.) and quite expensive. Producing a large area molybdenum target requires a significant capital investment. A large area (i.e., 1.8 m×2.2 m×10 mm) one piece molybdenum target may cost as much as $15,000,000 to produce. Therefore, for cost considerations alone, it would be beneficial to utilize a plurality of smaller targets, but still achieve the deposition uniformity of a large area sputtering target. The plurality of targets may be the same composition or a different composition.

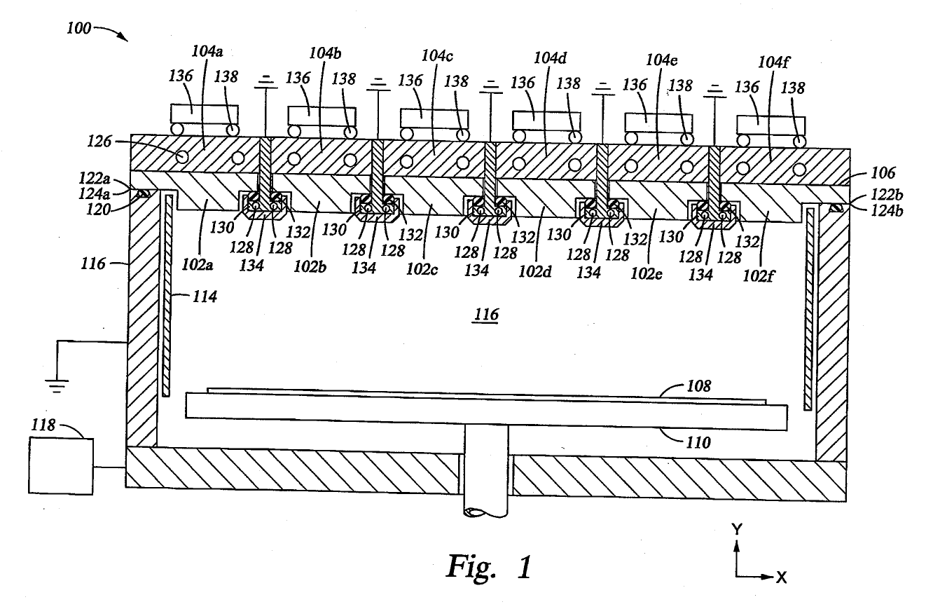

When utilizing a plurality of sputtering targets, it may be beneficial to have a corresponding magnetron for each target. FIG. 1 is a cross sectional view of a PVD apparatus 100 according to one embodiment of the invention that utilizes a plurality of sputtering targets 102a-102f, each with a corresponding magnetron 136. Each sputtering target 102a-102f may be coupled with a backing plate 104a-104f with a bonding layer 106 coupled between. A substrate 108 may be positioned on a susceptor 110 across a processing space 116. The chamber walls 112 of the apparatus 100 may be shielded by a shield 114—that circumscribes the processing space 116. The edge sputtering targets 102a, 102f may form a seal with the chamber walls 112 by a sealing member 120, and sealing surfaces 122a, 122b, 124a, 124b. In one embodiment, the sealing member 120 may be an O-ring. A controller 118 may control any movement of the susceptor, movement of the magnetrons 136 and bias applied to the targets 102a-102f.

Each backing plate 104a-104f may have one or more cooling channels 126 formed therein. The cooling channels may control the temperature of the backing plates 104a-104f as well as the sputtering targets 102a-102f. By controlling the temperature of the sputtering targets 102a-102f, any expansion and contraction due to temperature changes may be reduced.

It is to be understood that while six sputtering targets 102a-102f with corresponding backing plates 104a-104f have been shown in FIG. 1, more or less sputtering targets 102a-102f and backing plates 104a-104f may be utilized. In one embodiment, a single backing plate may be used with a plurality of sputtering targets coupled therewith.

An anode 130 may be positioned between adjacent sputtering targets 102a-102f. As may be seen in FIG. 1, the anodes may be grounded. The anode 130 may be shielded from any sputter deposition by a shield 134. The anodes 130 may be electrically isolated from the sputtering targets 102a-102f by a sealing member 132. In one embodiment, the sealing member 132 may be an O-ring. The anode 130 may also comprise one or more cooling channels 128. The cooling channels 128 may control the temperature of the anode 130 as well as the shield 134. By controlling the temperature of the anode 130 and thus, the shield 128, any expansion and contraction of the shield 128 and the anode 130 may be reduced. By reducing the expansion and contraction of the anode 130 and the shield 128, flaking may be reduced. Flaking occurs when material deposited on a surface flakes off and thus, contaminate a substrate 108. Flaking may occur as a result of expansion and contraction of the surface upon which material is deposited.

Each magnetron 136 may have one or more rollers 138 upon which the magnetron 136 may move across a surface of the backing plate 104a-104f. The rollers 138 permit the magnetrons 136 to translate across the backing plate 104a-104f within a plane. By translating a magnetron 136 across the back surface of the backing plate 104a-104f, the magnetic field created by the magnetron 106 may translate across the sputtering target 102a-102f. By translating the magnetic field across the sputtering target 102a-102f, material may be sputtered from a greater area of the targets 102a-102f.

As material is sputtered from the sputtering targets 102a-102f, the sputtering targets 102a-102f are considered to be “eroding”. By translating the magnetrons 136 and hence, the magnetic field, atoms may be sputtered from different areas of the sputtering target 102a-102f. Controlling the translation of the magnetron 136 may enable a technician to ensure that the target 102a-102f is uniformly eroded. For example, as more material is sputtered from a particular location on the sputtering target 102a-102f, the magnetron 136 may be translated and hence, translate the magnetic field. The magnetic field may be translated to a location on the sputtering target 102a-102f where less material has been sputtered. Thus, translating the magnetron 136 across the back of the backing plate 104a-104f may permit more uniform target 102a-102f erosion and hence, a longer target 102a-102f life.

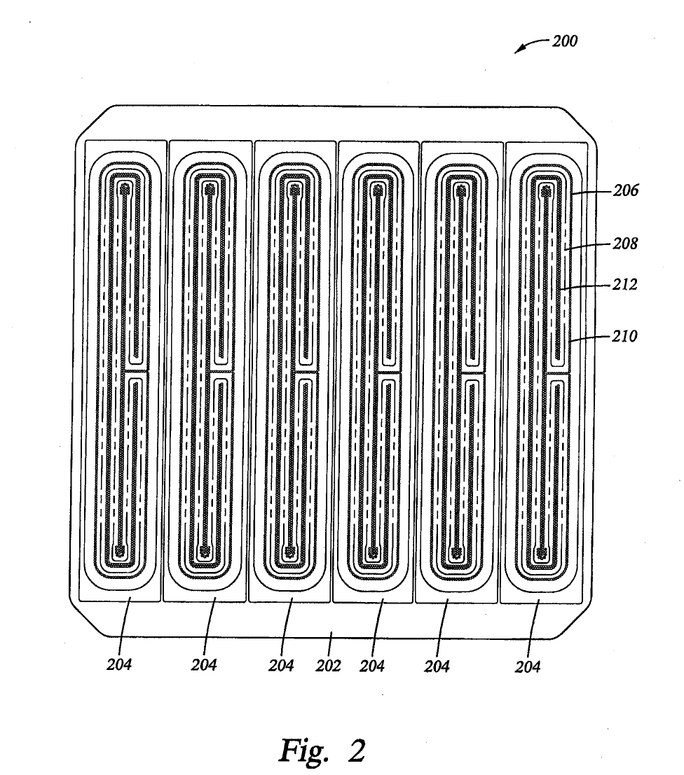

FIG. 2 is a top view of a magnetron assembly 200 according to one embodiment of the present invention. A plurality of magnetrons 204 may be spaced across the back surface of a backing plate assembly 202. Each magnetron 204 may comprise a plurality of magnets 206. In one embodiment, the magnets 206 may be cylindrical magnets. In another embodiment, the magnets 206 may be bar shaped magnets. In yet another embodiment, some of the magnets 206 may be cylindrical and some of the magnets 206 may be bar shaped. Each of the magnetrons 204 creates a magnetic field track 208.

The magnets 206 may be positioned across the magnetron 204 in an arrangement to create the magnetic field track 208 between adjacent magnet arrays. For example a plurality of magnets 206 may be coupled together to create a first magnet array 210. Additionally, another plurality of magnets 206 may be coupled together to create a second magnet array 212. In one embodiment, the two magnet arrays 210, 212 are magnetically isolated from one another so that one magnetic array 210 may be positioned with the north pole oriented downwards towards the backing plate assembly 202 and the second magnetic array 212 may be positioned with the south pole oriented downwards towards the backing plate assembly 202. Thus, the magnetic field track may be created in an area between the magnetic arrays 210, 212. The spacing between the magnetic arrays 210, 212 is referred to as the pitch.

The layout of the magnetic arrays 210, 212 and the relation of the magnetic arrays 210, 212 to each other determines the shape of the magnetic field track 208. As shown in FIG. 2, the magnetic arrays 210, and 212 for each magnetron 204 may be positioned to create a magnetic field track 208 having multiple turns.

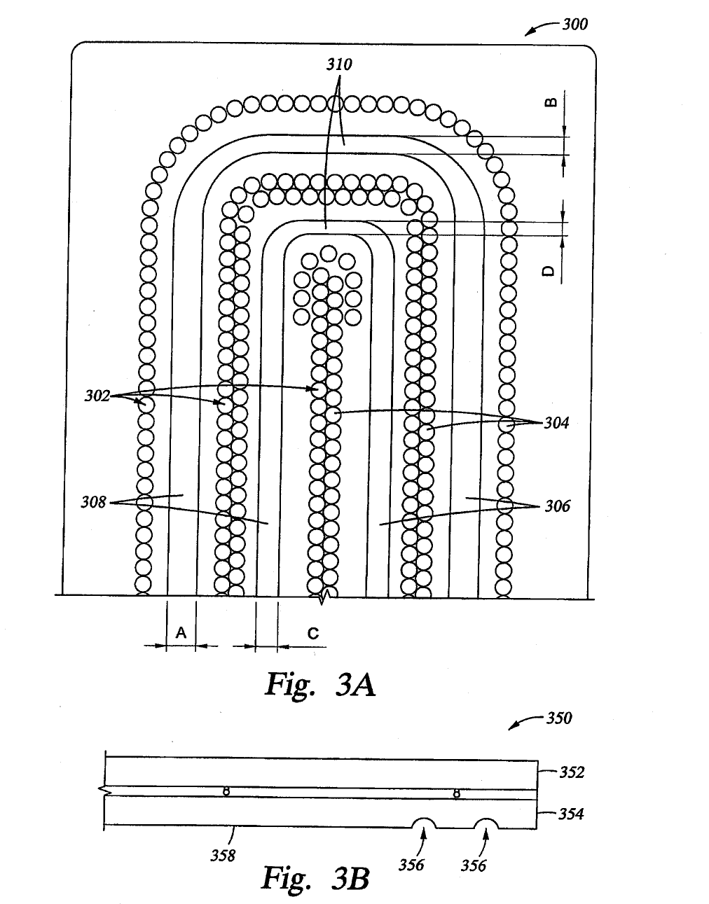

FIG. 3A is a partial schematic view of a magnetron assembly 300 with the corresponding magnetic field 306. The magnetron assembly 300 includes a plurality of magnet arrays 302. Each magnet array 302 has a plurality of magnets 304. The magnets 304 in adjacent arrays 302 may be arranged in a north-south arrangement such that a magnetic field 306 develops between the magnet arrays 302. The magnetic field 306 in FIG. 3A is a racetrack shaped magnetic field 306 having multiple turns. FIG. 3A shows two of the turns in the racetrack shaped magnetic field 306. The magnetic field 306 at the turn 310 may be pinched as compared to the straight track portions 308 of the magnetic field 306. The pinch in the magnetic field 306 means that the magnetic field 306 is narrowed as shown by arrows “B” and “D” when compared to the straight portions 308 of the magnetic field 306 as shown by arrows “A” and “C”. The pinched magnetic field 306 leads to a greater concentration of ions due to the stronger magnetic field 306 that may sputter more material from the areas of the sputtering target corresponding to the turns 310.

Pinching is due to the ions in the racetrack magnetic field 306 moving along the straight portions 308 at a particular speed and then slowing down as they move through the turns 310. Because the ions slow down moving through the turns 310, the ions tend to bunch up and have a greater concentration at the turns 310. With a greater concentration of ions at the turns 310, more material may sputter from the target.

FIG. 3B is a partial cross sectional view of a sputtering target assembly 350 having non-uniform sputtering target erosion due to a magnetic field pinching effect. The magnetron 352 disposed behind the sputtering target 354 may be similar to the magnetron discussed above in FIG. 3A. The pinched magnetic field may lead to deep erosion grooves 356 in the sputtering surface 358. The deep erosion grooves 356 are evidence of non-uniform sputtering surface 358 erosion.

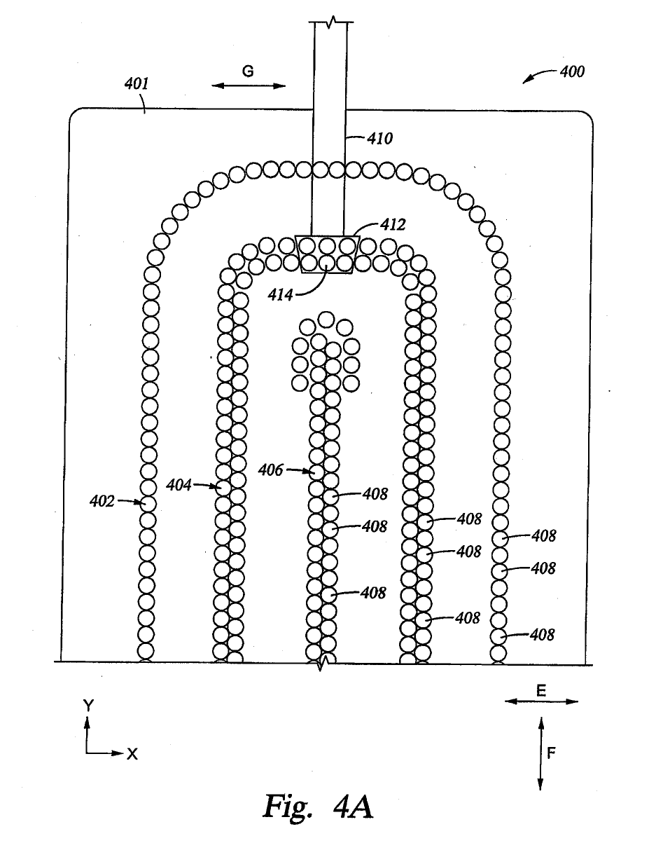

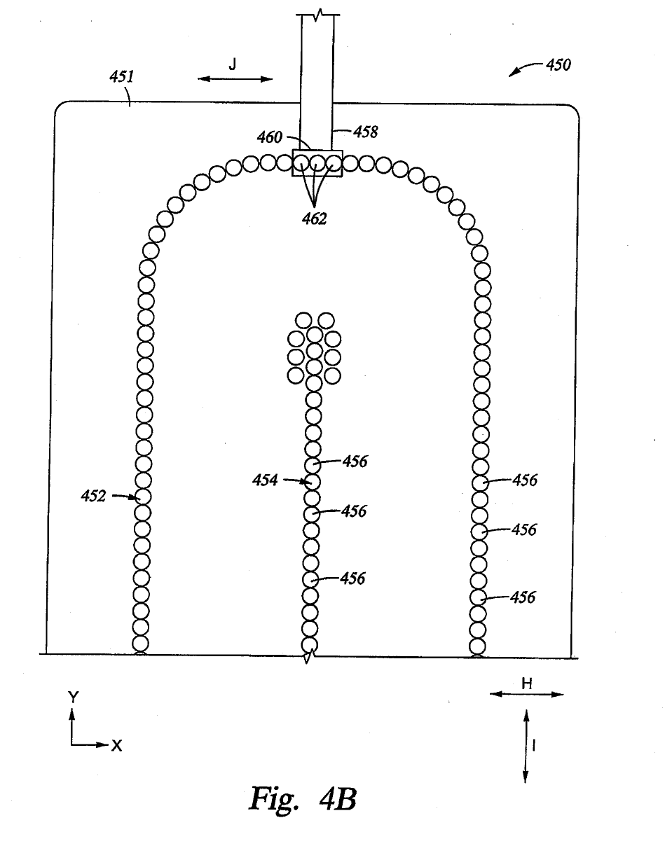

FIG. 4A is a partial schematic view of a magnetron assembly 400 according to one embodiment of the invention. The magnetron assembly 400 includes a middle magnet array 404 enclosed by two magnet arrays 402, 406. Each magnet array 402, 404, 406 has a plurality of magnets 408 and is disposed on a yoke 401. The middle magnet array 404 may have one or more magnets 414 disposed within a head 412 disposed on the end of an arm 410. The arm 410 may be disposed so that it does not block the line of sight of the magnetic field. In one embodiment, the arm 410 may be disposed within the yoke 401. In another embodiment, the arm 410 may be disposed behind the yoke 401.

The magnetron assembly 400 may move in all directions in the X-Y plane as represented by the arrows “E” and “F”. The arm 410, on the other hand, may move in only one direction within the X-Y plane as shown by the arrows “G”. As the magnetron assembly 400 moves in the direction represented by arrows “E”, the arm 410 will also move in the same direction as shown by arrows “G”. However, whenever the magnetron assembly 400 moves in the direction represented by arrows “F”, the arm 410 will remain stationery. When the arm 410 is stationary and the magnetron assembly 400 is moving, the magnets 414 disposed in the head 412 may swing or pivot compared to the other magnets 408 as will be described in detail below.

Similar to FIG. 4A, FIG. 4B is a partial schematic view of a magnetron assembly 450 according to another embodiment of the invention. In the embodiment depicted in FIG. 4B, the magnetron assembly 450 comprises an inner magnet array 454 and an outer magnet array 452. Each magnet array 452, 454 comprises a plurality of magnets 456 disposed on a yoke 451. The magnetron assembly 450 may move in all directions in the X-Y plane as represented by arrows “H” and “I”. One or more magnets 462 may be disposed in a head 460 disposed on the end of an arm 458. The arm 458 may move in only one direction within the X-Y plane as shown by arrows “J”. As the magnetron assembly 450 moves in the direction represented by arrows “H”, the arm 458 will move as well as shown by arrows “J”. However, when the magnetron assembly 450 moves in the direction shown by arrows “I”, the arm 458 will remain stationary.

In the magnetron assemblies 400, 450 of FIGS. 4A and 4B, when the arms 410, 458 are stationary in relation to the magnetron assemblies 400, 450, the magnets 414, 462 disposed within the heads 412, 460 may swing or pivot to thereby alter the magnetic field.

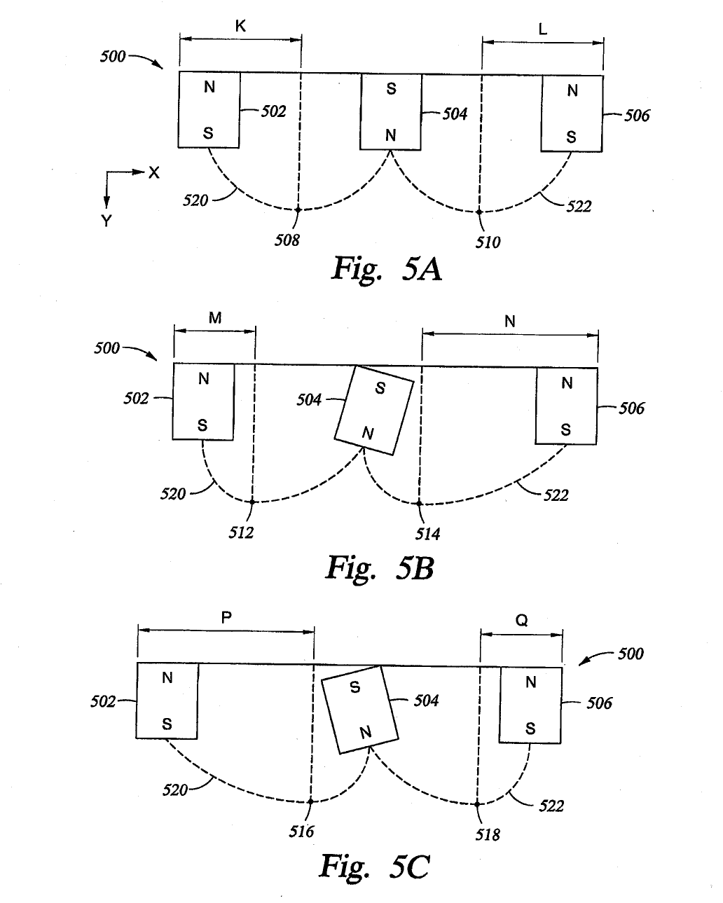

FIGS. 5A-5C are schematic cross-sectional views of a magnetron assembly 500 having a swinging magnet 504 at various locations according to one embodiment of the invention. The swinging magnet 504 may be equidistant between magnets 502 and 506. The magnetron assembly 500 shown in FIGS. 5A-5C shows three magnets 502, 504, 506 representing inner, middle, and outer magnetic arrays respectively. The magnets 502, 504 are arranged such that the magnetic field 520 generated by the magnets 502, 504 has a point 508 where the Y-component of the magnetic field substantially equals zero and is substantially equidistant between the magnets 504, 506. In other words, at point 508, the magnetic field perpendicular to the sputtering surface would equal zero.

Similarly, magnets 504, 506 are arranged such that the magnetic field 522 generated by the magnets 504, 506 has a point 510 where the Y-component of the magnetic field substantially equals zero and is substantially equidistant between the magnets 504, 506. In other words, at point 510, the magnet field perpendicular to the sputtering surface would equal zero.

Arrows “K” and “L” show the distance between the points 508, 510 and the edge of the magnets 502, 506. The distance represented by arrows “K” and “L” are substantially equal. At the points 508, 510 where the magnet fields 520, 522 are substantially zero in the Y-component direction, the concentration of ions will be greatest and hence, cause a greater amount of sputtering to occur. The concentration of ions is greatest because the magnetic field is deepest at the location where the Y-component is substantially equal to zero. Thus, the magnetic fields 520, 522 will result in a greater amount of sputtering from a location on the sputtering surface of the target corresponding to the points 508, 510 where the Y-component of the magnetic fields 520, 522 substantially equals zero. When the pinching associated with a racetrack magnetic field is considered in conjunction with the points where the Y-component of the magnetic fields substantially equals zero, it is easy to see that a greater erosion of sputtering target surface will occur at the turns of the magnetic field.

FIG. 5B shows magnet 504 swung or pivoted as compared to its position in FIG. 5A. The magnet may be swung or pivoted due to the arm 410 (see FIG. 4A) remaining stationary as the magnetron assembly moves. By pivoting or swinging the middle magnet 504, the point 512 where the Y-component of the magnetic field 520 substantially equals zero has shifted to be closer to inner magnet 502 as represented by arrows “M”. The distance represented by arrows “M” is less than the distance represented by arrows “K”. Similarly, due to the pivoting of the middle magnet 504 away from the outer magnet 506, the point 514 in the magnetic field 522 where the Y-component of the magnetic field 522 is substantially equal to zero shifts so that the point 514 is farther away from the magnet 506 as represented by arrows “N”. The distance represented by arrows “N” is greater than the distance represented by arrows “L”. For both magnetic fields 520, 522, the points 512, 514 where the Y-component of the magnetic fields 520, 522 are substantially equal to zero is still substantially equidistant between the magnets (i.e., 502 and 504 for point 512; 504 and 506 for point 514), but the location in relation to the magnets 502, 504 has changed.

In FIG. 5C, the middle magnet 504 has pivoted or swung the opposite direction as compared to FIG. 5B. In a manner similar to FIG. 5B, the point 516 in the magnetic field 520 where the Y-component of the magnetic field 520 substantially equals zero has shifted further away from the inner magnet 502 as shown by arrows “P”. The distance represented by arrows “P” is greater than the distance represented by arrow “K” and arrow “M”. Because the middle magnet 504 has pivoted or swung closer to the outer magnet 506, the point 518 in the magnetic field 522 where the Y-component of the magnetic field 522 substantially equals zero has shifted closer to the outer magnet 506 as shown by arrows “Q”. The distance represented by arrows “Q” is less than the distance represented by arrows “N” and arrows “L”. For both magnetic fields 520, 522, the points 516, 518 where the Y-component of the magnetic fields 520, 522 is substantially equal to zero are still substantially equidistant between the magnets (i.e., 502 and 504 for point 516; 504 and 506 for point 518), but the location in relation to the magnets 502, 504 has changed.

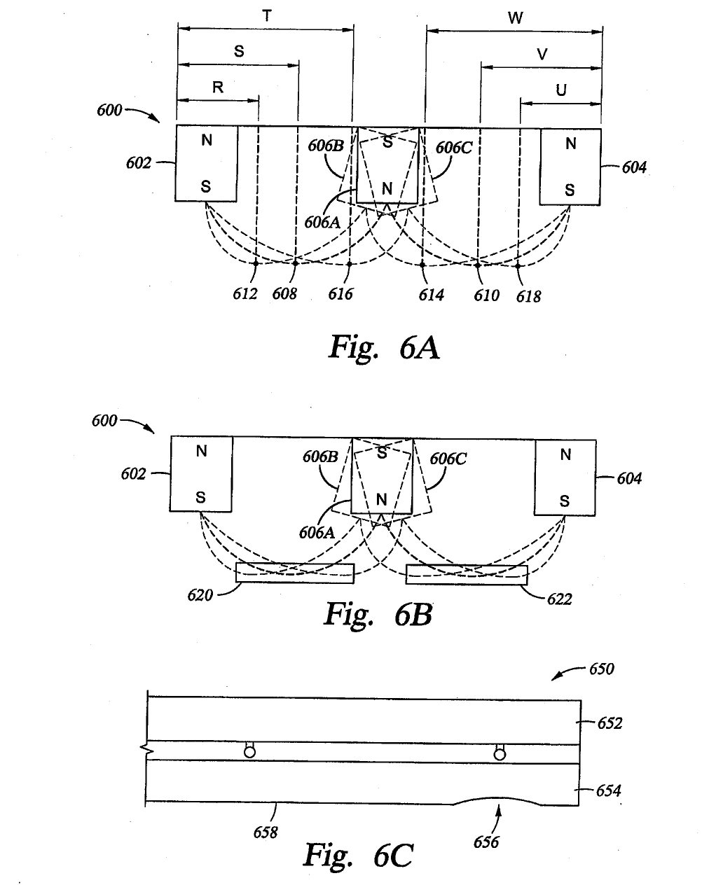

FIG. 6A is a schematic view of various locations showing the point where the Y-component of the magnetic field is substantially equal to zero as the magnets swing or pivot. The magnetron assembly 600 depicted in FIG. 6A has an inner magnet 602, outer magnet 604, and a middle magnet (shown in three positions 606A, 606B, 606C) during magnetron assembly 600 movement. When the middle magnet is in position 606A, the points 608, 610 where the Y-component of the magnetic field is substantially equal to zero are substantially an equidistant between position 606A and magnet 604 as between position 606A and magnet 602. Arrows “S” and “V” represent the distance between the magnets 602, 604 and position 606A. Arrows “S” and “V” represent substantially equal distances.

Once the middle magnet has swung or pivoted to position 606B, the point 612 in the magnetic field where the Y-component of the magnetic field is substantially equal to zero is closer to the inner magnet 602 as compared to point 608. Arrows “R” represent the distance between the inner magnet 602 and the position 606B. Arrows “R” represent a shorter distance than arrows “S”. Similarly, when the middle magnet has swung to position 606B, the point 614 in the magnetic field where the Y-component of the magnetic field is substantially equal to zero is closer to the position 606B as compared to point 610. Arrows “W” represent the distance between the outer magnet 604 and the position 606B. Arrows “W” represent a longer distance than arrows “V”.

When the middle magnet has swung or pivoted to position 606C, the point 616 in the magnetic field where the Y-component of the magnetic field is substantially equal to zero is closer to the position 606C as compared to point 608. Arrows “T” represent the distance between the inner magnet 602 and the position 606B. Arrows “T” represent a longer distance than arrows “S”. Similarly, when the middle magnet has swung to position 606C, the point 618 in the magnetic field where the Y-component of the magnetic field is substantially equal to zero is closer to the outer magnet 604 as compared to point 610. Arrows “U” represent the distance between the outer magnet 604 and the position 606B. Arrows “U” represent a longer distance than arrows “V”.

When the inner magnet 602 and outer magnet 604 are equally spaced from the inner magnet, the distance represented by arrows “S” is substantially equal to the distance represented by arrows “V”. Likewise, the distance represented by arrows “R” is substantially equal to the distance represented by arrows “U”. Finally, the distance represented by arrows “T” is substantially equal to the distance represented by arrows “W”.

It is to be understood that while the middle magnet has been shown in three positions 606A, 606B, 606C, other positions may be used. For example as the middle magnet pivots or swings from position 606A to 606B, the point where the Y-component of the magnetic field substantially equals zero moves from point 608 to point 612 and from point 610 to point 614. Likewise, when the middle magnet pivots or swings from position 606A to 606C, the point where the Y-component of the magnetic field substantially equals zero moves from point 608 to point 6116 and from point 610 to point 618.

FIG. 6B is a schematic view of the average of the various locations where the Y-component of the magnetic field is substantially equal to zero as the magnets swing or pivot. As may be seen in FIG. 6B, because the middle magnet swings or pivots between location 606B and 606C, the location where the Y-component of the magnetic field substantially equals zero moves and creates an area 620, 622 for each magnetic field as opposed to a single point. The areas 620, 622 represent the locations within which the Y-component of the magnetic field substantially equals zero exists over time as the middle magnet pivots or swings between position 606B and 606C.

FIG. 6C is a schematic cross sectional view of a sputtering target assembly 650 with corresponding target erosion resulting from a swinging magnet. The magnetron assembly 652 disposed behind the sputtering target 654 may create a more uniform erosion cavity 656 in the sputtering surface 658. The erosion corresponds to the turns in the racetrack magnetic field when using a swinging or pivoting magnet in the magnetron assembly 652.

It is to be understood that while FIGS. 5A-5C and 6A-6B exemplify only one inner magnet, one outer magnet, and one middle magnet, the magnets are representative of a magnetron assembly having one or more inner magnets, one or more middle magnets, and one or more outer magnets. One or more middle magnets may be swung or pivoted to adjust the location where the Y-component of the magnetic field substantially equals zero. Additionally, it is contemplated that the outer magnets and/or inner magnets may be pivoted or swung either alternatively to or in combination with the middle magnets. For a magnetron having two magnet arrays, one or more outer magnets and/or one or more inner magnets may pivot or swing to adjust the location where the Y-component of the magnetic field substantially equals zero.

Pivoting or swinging one or more magnets within a magnetron assembly may enlarge the area where the Y-component of the magnetic field substantially equals zero. By enlarging the area, the erosion profile for a sputtering target may be flatter. Thus, swinging or pivoting one or more magnets in a magnetron assembly may enhance sputtering target erosion uniformity and lengthen the useful life of a sputtering target.

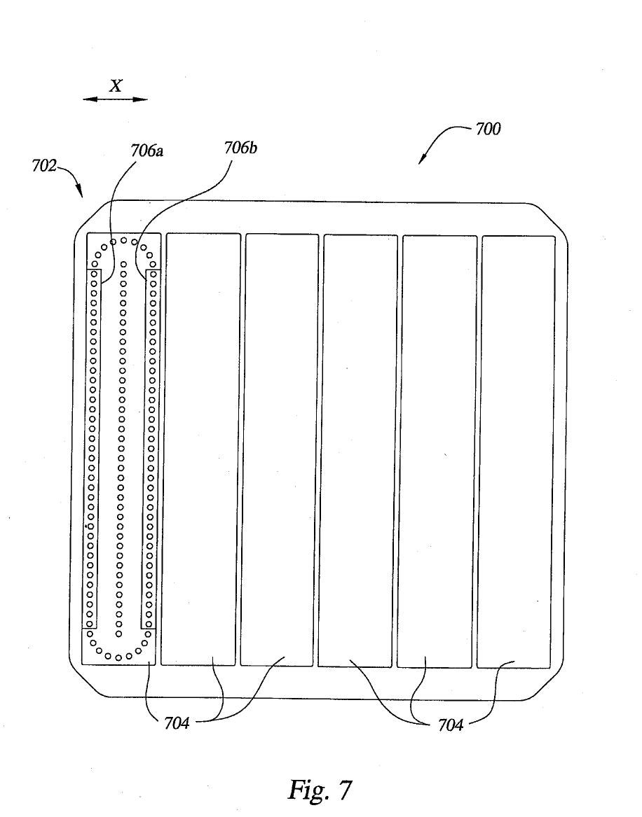

FIG. 7 is a schematic top view of a magnetron assembly 700 according to another embodiment of the invention. The magnetron 702 may move as shown by arrows “X” across the back of multiple targets 704. When the magnetron 702 reaches an end target, erosion may be greater, therefore, areas 706a, 706b of the magnetron 702 may be swung or pivoted, as described above, to reduce the amount of erosion that occurs on the target and aid in uniform target 704 erosion.

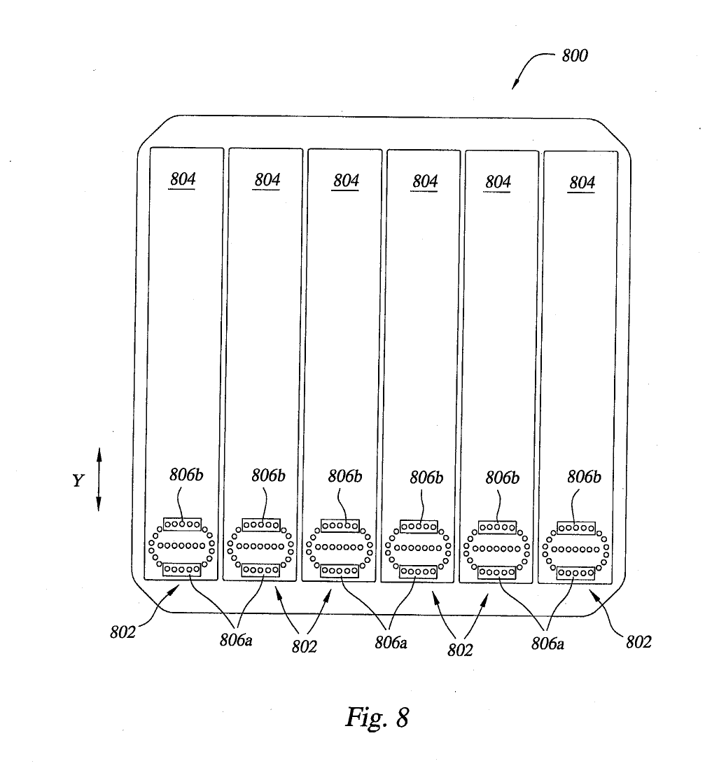

FIG. 8 is a schematic top view of a magnetron assembly 800 according to another embodiment of the invention. A small magnetron 802 may scan across the back of a sputtering target 804 lengthwise as shown by arrows “Y”. When the magnetron 802 reaches the end of the target 804, erosion may be greater, therefore, areas 806a, 806b of the magnetron 802 may be swung or pivoted, as described above, to reduce the amount of erosion that occurs on the target and aid in uniform target 804 erosion.

While the foregoing is directed to embodiments of the present invention, other and further embodiments of the invention may be devised without departing from the basic scope thereof, and the scope thereof is determined by the claims that follow.

1. A sputtering apparatus, comprising:
a magnetron assembly, the magnetron assembly arranged in a racetrack pattern and comprising a plurality of magnets;
one or more movement devices coupled with the magnetron assembly capable of providing movement to the magnetron assembly; and
a restraining mechanism coupled with one or more magnets within the magnetron assembly capable of producing a swinging movement of the one or more magnets within the magnetron assembly.

2. The apparatus of claim 1, wherein the one or more movement devices are capable of moving the magnetron assembly in multiple directions within a plane.

3. The apparatus of claim 2, wherein the restraining mechanism is movable in only one direction within the plane.

4. The apparatus of claim 1, further comprising:
one or more additional magnets that are stationary in relation to the one or more magnets coupled with the restraining mechanism.

5. The apparatus of claim 1, wherein the racetrack pattern comprises two or more turns.

6. A sputtering apparatus, comprising:
a moveable magnetron assembly having a plurality of magnets therein, the magnetron assembly moveable as a whole within a plane; and
an arm moveable in only one direction within the plane coupled with one or more magnets within the magnetron assembly.

7. The apparatus of claim 6, wherein the moveable magnetron assembly comprises at least two magnet arrays.

8. The apparatus of claim 6, wherein the magnetron assembly comprises a magnet array arranged such that a racetrack shaped magnetic field is created.

9. The apparatus of claim 8, wherein the racetrack shaped magnetic field comprises two or more turns.

10. The apparatus of claim 6, wherein the one or more magnets coupled with the arm are pivotable relative to other magnets within the magnetron assembly.

11. A magnetron assembly, comprising:
a magnet support;
a plurality of magnets coupled with the magnet support;
one or more movement devices coupled with the magnet support capable of moving the magnet support within a plane; and
an arm moveable in only one direction within the plane and coupled with one or more magnets of the plurality of magnets.

12. The magnetron assembly of claim 11, wherein the one or more movement devices are capable of moving the magnet support in multiple directions within a plane.

13. The magnetron assembly of claim 11, wherein the one or more magnets coupled with the arm are pivotable relative to other magnets coupled with the magnet support.

14. The magnetron assembly of claim 11, further comprising:
one or more additional magnets that are stationary in relation to the one or magnets coupled with the arm.

15. The magnetron assembly of claim 11, wherein the plurality of magnets are arranged in a magnet array such that a racetrack shaped magnetic field is created.

16. The magnetron assembly of claim 15, wherein the racetrack shaped magnetic field comprises two or more turns.

17. A sputtering method, comprising:
moving a magnetron assembly behind a sputtering target assembly, the magnetron assembly comprising a plurality of magnets; and
swinging one or more magnets within the magnetron assembly as the magnetron assembly moves.

18. The method of claim 17, wherein the moving comprises moving the magnetron assembly in multiple directions within a plane.

19. The method of claim 17, wherein the one or more magnets swing in relation to additional magnets within the magnetron assembly.

20. The method of claim 17, wherein the magnetron assembly is arranged to produce a racetrack shaped magnetic field comprising two or more turns.

21. A sputtering method, comprising:
moving a magnetic field across a face of a sputtering target, the magnetic field comprising a point where the magnetic field consists of a component parallel to the target face; and
changing a location of the point within the magnetic field as the magnetic field moves.
